(19) United States
(12) Patent Application Publication
(10) Pub. No.: US 2012/0140412 A1
(43) Pub. Date: Jun. 7, 2012

(54) POWER MODULE FOR INVERTER

(75) Inventors: Dongmin Shin, Hwaseong (KR); Wooyong Jeon, Seoul (KR); In Pil Yoo, Seoul (KR); Joon Hwan Kim, Seoul (KR); Ki-young Jang, Hwaseong (KR); Sangcheol Shin, Suwon (KR); Minji Kim, Hwaseong (KR); Youngkook Lee, Seoul (KR); Jin Hwan Jung, Suwon (KR); Jung Hong Joo, Hwaseong (KR)

(73) Assignees: KIA MOTORS CORPORATION, Seoul (KR); HYUNDAI MOTOR COMPANY, Seoul (KR)

(21) Appl. No.: 13/183,629

(22) Filed: Jul. 15, 2011

(30) Foreign Application Priority Data
Dec. 6, 2010 (KR) 10-2010-0123448

(51) Int. Cl. H05K 7/20; H05K 7/00

(52) U.S. Cl. 361/688; 361/728; 361/747

(57) ABSTRACT

A power module for an inverter which includes a base which has a plurality of slots are formed thereto, a plurality of building blocks inserted into the slots and power cables interconnecting the building blocks. Further, each of these building blocks is provided with a power element which corresponds to one phase. Thus, each building block in the power module may be replaced individually without having to replace the entire power module in case of a failure in a single power element of the power module.

### CROSS-REFERENCE TO RELATED APPLICATION

This application claims priority to and the benefit of Korean Patent Application No. 10-2010-0123448 filed in the Korean Intellectual Property Office on Dec. 6, 2010, the entire contents of which are incorporated herein by reference.

### BACKGROUND OF THE INVENTION

(a) Field of the Invention

The present invention relates to a power module. More particularly, the present invention relates to a power module for an inverter of a hybrid/electric vehicle.

(b) Description of the Related Art

An electric vehicle, a hybrid vehicle, a fuel cell vehicle typically utilize a motor which operates via a permanent magnet. The motor is driven by phase current which is supplied from an inverter through a power cable. This phase current is converted from direct current (DC) voltage into 3-phase alternating current (AC) voltage according to a PWM (Pulse Width Modulation) signal of a controller.

Generally, a power module combines three-phases or six-phases into one package to provide physical containment for several power components, e.g. semi-conductor devices, and thus even if one element malfunctions, the entire package must be discarded. Thus, manufacturing efficiency is often quite low and a new design is required which allows for a more efficient design.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention provides a power module for an inverter which may separately dispose each phase and allows for repair of a single corresponding block if a partial malfunction or damage occurs in that block of the power module. Also, the present invention provides a power module which may have universal parts and may be applied to a variety of power modules by packaging.

A power module for an inverter according to an exemplary embodiment of the present invention may include a base of which a plurality of slots are formed thereto, a plurality of building blocks inserted into the slots and power cables interconnecting the building blocks. Each of the building blocks is provided with a power element corresponding one phase.

A connecting hole/aperture may be formed in the building block for connecting to the base. Additionally, the plurality of building blocks may include a U phase block, a V phase block and a W phase block and may further include a building block provided with a DC booster. Furthermore, a cooling line may be formed within the base.

The power module for an inverter according to an exemplary embodiment of the present invention may separately dispose each phase and may change corresponding blocks if a partial malfunction or damage to that corresponding block occurs without have having to discard the entire power module. Further, because each block is separately specified, the entire element may be packaged so that it may be applied to a variety of power module.

Therefore, the power module for an inverter according to an exemplary embodiment of the present invention may enhance yield and reduce manufacturing cost. In addition, a variety of voltage/current specifications may be applied and universal use of power module packaging may be possible and thus standardization of a power module may be possible as well.

### BRIEF DESCRIPTION OF THE DRAWINGS

FIG. 1 is a perspective view showing a power module for an inverter according to an exemplary embodiment of the present invention.

FIG. 2 is a circuit diagram of a hybrid inverter according to an exemplary embodiment of the present invention.

FIG. 3 is a developed diagram showing a power module for an inverter according to an exemplary embodiment of the present invention.

### DESCRIPTION OF SYMBOLS

10: base

12: cooling line

20: slot

30: building block

32: connecting hole

40, 42: power cable

### DETAILED DESCRIPTION OF THE EMBODIMENTS

Reference will now be made in detail to various embodiments of the present invention(s), examples of which are illustrated in the accompanying drawings and described below. While the invention(s) will be described in conjunction with exemplary embodiments, it will be understood that present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than to petroleum). As referred to herein, a hybrid vehicle is a vehicle that has two or more sources of power, for example both gasoline-powered and electric-powered vehicles.

An exemplary embodiment of the present invention will hereinafter be described in detail with reference to the accompanying drawings.

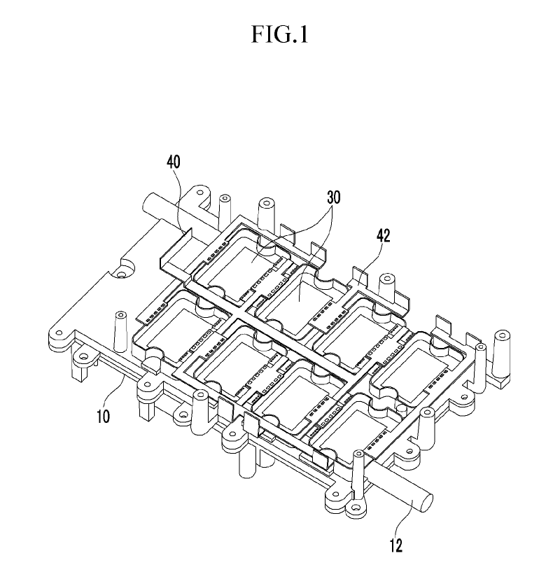

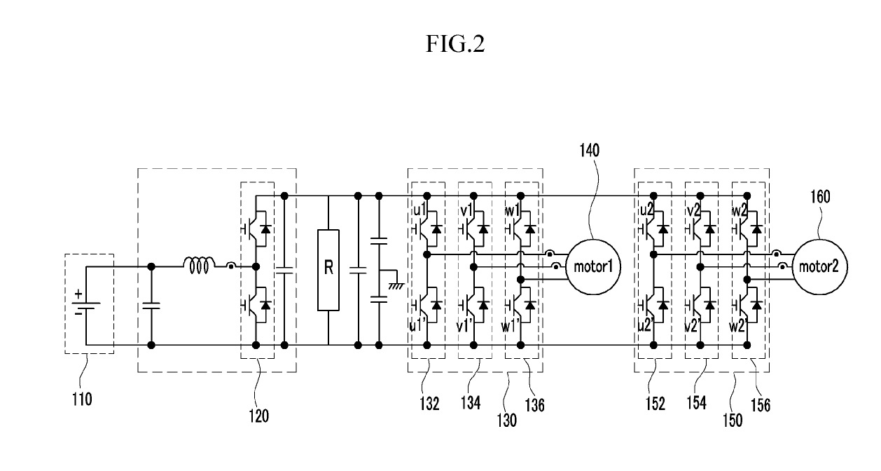

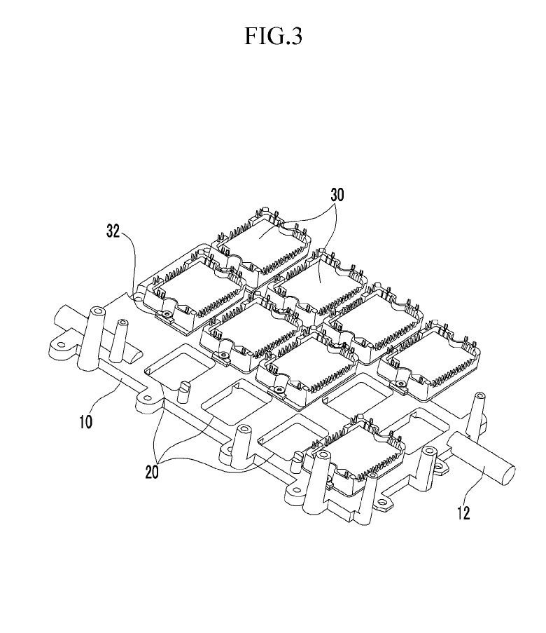

FIG. 1 is a perspective view showing a power module for an inverter according to an exemplary embodiment of the present invention and FIG. 3 is a developed diagram showing a power module for an inverter according to an exemplary embodiment of the present invention. FIG. 2 is a circuit diagram of a hybrid inverter according to an exemplary embodiment of the present invention.

Referring to FIG. 2, a power module for an inverter according to an exemplary embodiment of the present invention includes a battery 110, a DC booster 120, a first inverter 130, a second inverter 150, a first motor 140 and a second motor 160. The first motor 140 maybe a 3-phase AC electric motor, which is operated as an electric motor to start an engine (not shown), and may be selectively operated as a generator driven by the engine. The first motor 140 may be operated by 3-phase AC voltage supplied through the first inverter 130 so as to start the engine. The second motor 160 may be a 3-phase AC electric motor for driving a driving wheel (not shown) and generating a driving torque by 3-phase AC voltage supplied from the second inverter 150.

The first inverter 130 is formed by connecting electric switching elements in series, and includes U phase arms, u and u′, V phase arms, v and v′, and W phase arms, w and w′. Either a Negative Positive Negative (NPN) transistor, an Insulated Gate Bipolar Transistor (IGBT), or a metal-oxide-semiconductor field-effect transistor (MOSFET) may be used as the electric switching element. The first inverter 130 converts the DC voltage of the battery 110 supplied through the DC booster 120 into the to 3-phase AC voltage according to a PWM signal applied to each arm and supplies the 3-phase AC voltage to the first motor 140 as a driving voltage.

The second inverter 150 is formed by connecting electric switching elements in series, and includes U phase arms, u and u′, V phase arms, v and v′, and W phase arms, w and w′. Again, either of an NPN transistor, an IGBT (Insulated Gate Bipolar Transistor), and an MOSFET may be used as the electric switching element. The second inverter 150 converts the DC voltage of the battery 110 supplied through the DC booster 120 into the 3-phase AC voltage according to a PWM signal applied to each arm and supplies the 3-phase AC voltage to the second motor 160 as a driving voltage.

Referring to FIG. 1 to FIG. 3, a power module for an inverter according to an exemplary embodiment of the present invention includes a base 10 of which a plurality of slots 20 are formed thereto, a plurality of building blocks 30 inserted into the slots 20 and power cables 40 and 42 interconnecting the building blocks 30.

In a case of a conventional power module for an inverter, one power module includes all of the power element, and thus if one element malfunctions, the entire package must be replaced. However, in the case of the power module for an inverter according to an exemplary embodiment of the present invention, each building block 30 has one power element corresponding each phase as seen in FIGS. 1 and FIGS. 3. That is, each power element 132, 134, 136, 152, 154 and 156 of each inverter 130 and 150 is respectively disposed and associated with a separate building block 30.

A connecting hole/aperture 32 is formed to the building blocks 30 to be connected to the base 10. The plurality of building blocks 30 includes a U phase block, a V phase block and a W phase block. The plurality of building blocks 30 may further include a building block 30 provided with the DC booster 120. A cooling line 12 is formed to the base 10 and cools each building block 30.

In FIG. 1 and FIG. 2, 8 building blocks 30 are shown and the building blocks 30 include the building blocks 30 of which each power element 132, 134, 136, 152, 154 and 156 is disposed, and two building blocks 30 of which the DC booster 120 are disposed respectively. However, the present invention is not limited to the drawings, variable modifications for applying each power element are also possible.

As described above, the power module for an inverter according to an exemplary embodiment of the present invention may separately dispose each phase and allow for replacement of a corresponding block if a partial malfunction or damage to a block occurs, and by specifically changing corresponding blocks, an entire element may be packaged so that it may be applied to variety of power module.

While this invention has been described in connection with what is presently considered to be practical exemplary embodiments, it is to be understood that the invention is not limited to the disclosed embodiments. On the contrary, it is intended to cover various modifications and equivalent arrangements included within the spirit and scope of the appended claims.

What is claimed is:

1. A power module for an inverter comprising:
a base of which a plurality of slots are formed thereto;
a plurality of separate building blocks configured to be inserted into the slots of the base; and
power cables interconnecting the building blocks, wherein each building block is provided with a power element corresponding one phase.

2. The power module of claim 1, wherein a connecting aperture is formed to the building block for connecting to the base.

3. The power module of claim 1, wherein the plurality of building blocks comprise a U phase block, a V phase block and a W phase block.

4. The power module of claim 3, wherein the plurality of building blocks further comprise a building block having a DC booster.

5. The power module of claim 1, wherein a cooling line is formed in the base.
